(19) United States
(12) Patent Application Publication
(10) Pub. No.: US 2026/0329169 A1
(43) Pub. Date: Oct. 22, 2026

(54) IMPRINT APPARATUS AND ARTICLE MANUFACTURING METHOD

(71) Applicant: CANON KABUSHIKI KAISHA, Tokyo (JP)

(72) Inventor: TOSHIHIRO OGATA, Tochigi (JP)

(21) Appl. No.: 19/630,989

(22) Filed: Mar. 27, 2026

(30) Foreign Application Priority Data
Apr. 18, 2025 (JP) 2025-068954

(51) Int. Cl. G03F 7/00

(52) U.S. Cl. CPC G03F 7/0002

(57) ABSTRACT

An imprint apparatus includes a first supplier that supplies a first gas for replacement with air in a space between a mold and a substrate. The first supplier has a first nozzle that injects the first gas. A peripheral region of the mold is provided with a first flow path from an end of the mold toward a mesa portion of the mold and a second flow path from the mesa portion toward the end of the mold. The first nozzle is arranged toward the first flow path so that the first gas is introduced into the first flow path, and when the first gas is supplied through the first flow path by the first supplier, a gas in the space is discharged to the outside through the second flow path.

### BACKGROUND

### Field of the Technology

The present disclosure relates to an imprint apparatus and an article manufacturing method.

### Description of the Related Art

An imprint apparatus cures an imprint material in a state where a mold and the imprint material on a substrate are in contact with each other, and separates the mold, thereby transferring a pattern to a substrate surface. By processing the substrate using the transferred pattern as a mask, a fine concavo-convex structure of several tens of nm to several nm can be formed, and an integrated circuit, a MEMS, a microlens array, or the like can be manufactured.

During pattern transfer using the imprint apparatus, gas may enter between the mold and the substrate, and a defect (bubble defect) may occur. As a countermeasure, in a process of transferring a pattern to a substrate surface by bringing a mold and an imprint material on a substrate into close contact with each other, a surrounding space between the mold and the substrate is replaced with a permeable process gas (gas purge). The process gas is a gas having excellent solubility and diffusivity (permeable gas). As the permeable gas, for example, hydrogen (H₂), helium (He), carbon dioxide (CO₂), or the like can be used.

Further, in order to prevent separation charging that occurs when a mold is released from a substrate, a surrounding space of the mold and the imprint material is replaced with a process gas having an anti-static effect. As the anti-static gas, for example, helium (He) or a charged gas that has passed through an ionizer can be used.

In Japanese Patent Application Laid-Open No. 2021-184435, for gas replacement, two sets of a through-hole for gas supply and a circular ring groove (flow path) for purging a process gas are formed in the periphery of a pattern region of a mold. In the gas replacement operation, first, a gas suction operation is performed from an inner first through-hole while a gas supply operation is performed from an outer second through-hole. Thereby, after a space sandwiched between the mold and the substrate is evacuated, control switching is performed so that the gas supply operation is performed also from the inner first through-hole.

However, there is still a problem in terms of throughput because a space through which gas flows is narrow even if purging is performed with a process gas, and gas replacement takes time.

### SUMMARY

The present disclosure provides a technique advantageous for achieving both reduction of defects and throughput.

The present disclosure in one aspect provides an imprint apparatus that transfers a pattern of a mold onto a substrate, including a first supplier that supplies a first gas for replacement with air in a space between the mold and the substrate, wherein the first supplier has a first nozzle that injects the first gas, wherein the mold has a mesa portion in which the pattern is formed and a peripheral region surrounding the mesa portion, and the peripheral region is provided with a first flow path from an end of the mold toward the mesa portion and a second flow path from the mesa portion toward the end of the mold, wherein the first nozzle is arranged toward the first flow path so that the first gas is introduced into the first flow path, and when the first gas is supplied through the first flow path by the first supplier, a gas in the space is discharged to the outside through the second flow path.

Features of the present disclosure will become apparent from the following description of embodiments with reference to the attached drawings. The following description of embodiments is described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a diagram showing a configuration of an imprint apparatus.

FIGS. 2A-2B are diagrams showing details of a mold and its periphery.

FIGS. 3A-3C are diagrams showing details of a mold and its periphery.

FIG. 4 is a diagram for explaining an arrangement relationship between a deformation mechanism and a nozzle.

FIG. 5 is a diagram for explaining a flow of gas during gas replacement.

FIG. 6 is a diagram explaining an article manufacturing method.

### DESCRIPTION OF THE EMBODIMENTS

Hereinafter, embodiments will be described in detail with reference to the attached drawings. Note that the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

First, an outline of an imprint apparatus according to an embodiment will be described. An imprint apparatus is an apparatus that forms a pattern of a cured product to which a concavo-convex pattern of a mold is transferred by bringing an imprint material supplied onto a substrate into contact with the mold and applying energy for curing to the imprint material.

As the imprint material, a curable composition (also referred to as an uncured resin) that is cured by being given energy for curing is used. As the energy for curing, an electromagnetic wave, heat, or the like can be used. The electromagnetic wave can be, for example, light whose wavelength is selected from a range of 10 nm or more and 1 mm or less, for example, infrared rays, visible light rays, ultraviolet rays, or the like. The curable composition can be a composition that is cured by light irradiation or by heating. Among these, a photocurable composition that is cured by light irradiation contains at least a polymerizable compound and a photopolymerization initiator, and may further contain a non-polymerizable compound or a solvent as necessary. The non-polymerizable compound is at least one selected from the group of a sensitizer, a hydrogen donor, an internal release agent, a surfactant, an antioxidant, a polymer component, and the like. The imprint material can be arranged on the substrate in a droplet form or an island or film form formed by connecting a plurality of droplets by an imprint material supply device (not shown). The viscosity of the imprint material (viscosity at 25 degrees C) can be, for example, 1 mPa·s or more and 100 mPa·s or less. As a material of the substrate, for example, glass, ceramics, metal, semiconductor, resin, or the like can be used. A member made of a material different from that of the substrate may be provided on the surface of the substrate as necessary. The substrate is, for example, a silicon wafer, a compound semiconductor wafer, or quartz glass.

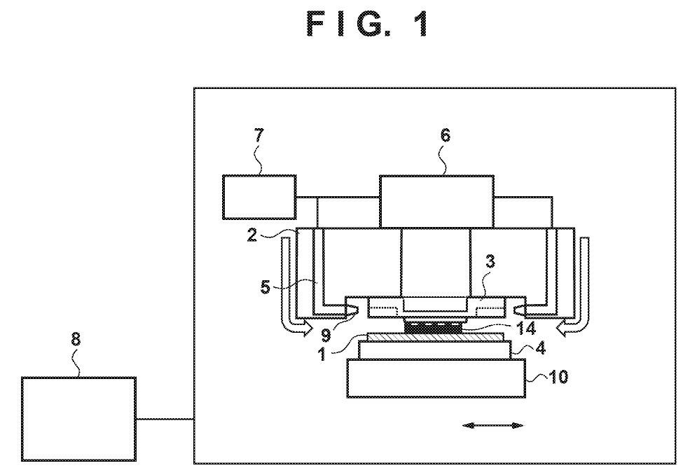

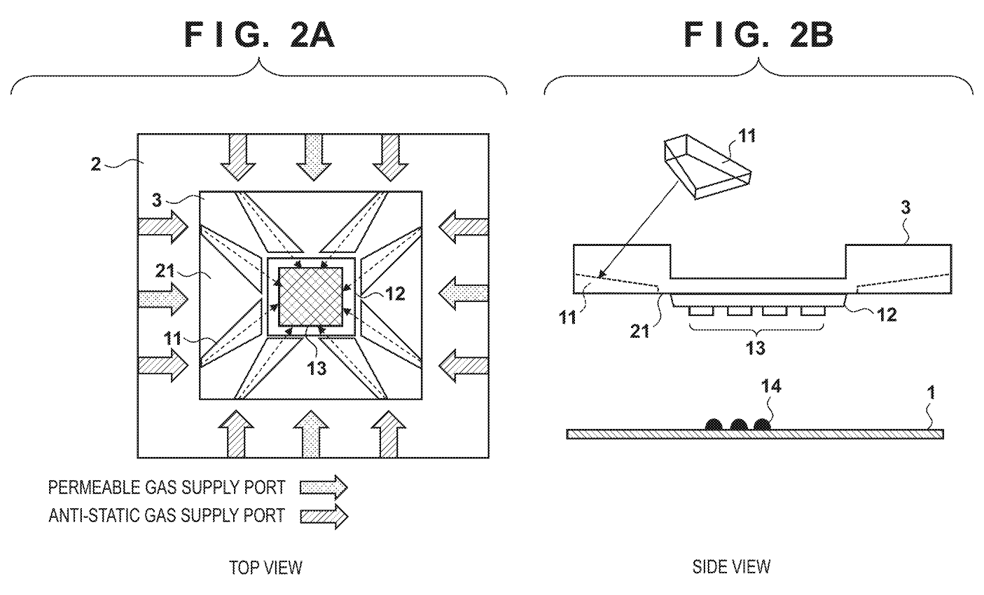

FIG. 1 is a schematic diagram illustrating a configuration of an imprint apparatus in an embodiment. FIGS. 2A-B are a top view and a side view showing details of a mold and its periphery. The imprint apparatus can include an imprint head 2, a substrate stage 10, a dispenser (not shown) which is an imprint material supply device, a UV light irradiation unit 6, and a gas pressure controller 7. The imprint apparatus can further include a system controller 8 which is a control unit.

An outline of the operation of the imprint apparatus will be described with reference to FIG. 1. An imprint material 14 is applied (supplied) onto a substrate 1. A mold 3 having a pattern (for example, a circuit pattern) and the imprint material 14 on the substrate are brought into contact with each other, and the pattern of the mold 3 is filled with the imprint material 14. Thereafter, the imprint material 14 is irradiated with UV light to cure the imprint material 14. The mold 3 is separated from the cured imprint material 14. Thereby, the pattern is transferred to the surface of the substrate 1.

The dispenser applies the imprint material 14 onto the substrate. The dispenser continuously drops the imprint material 14 of about one drop volume (0.5 to 6 pL) onto the substrate, and performs application of the imprint material 14 to the substrate 1. As an application technique of the imprint material 14, a technique of discharging a material drop by drop from a nozzle similarly to an inkjet printer can be used. Therefore, the imprint material 14 can be applied to a desired position on the substrate surface by continuously discharging the material while the substrate stage 10 relatively moves the substrate 1 with respect to a plurality of nozzles arranged in a line.

The substrate stage 10 holds the substrate 1 via a substrate chuck 4. The holding of the substrate is performed by, for example, a vacuum chuck or an electrostatic chuck. The system controller 8 controls the substrate stage 10 so that the substrate 1 is located directly below the dispenser. Thereafter, the system controller 8 can apply the imprint material 14 to a desired position on the substrate surface by discharging the imprint material from the dispenser while scan-driving the substrate stage 10.

The imprint head 2 can include a vacuum type mold chuck. The imprint head 2 holds the mold 3 via the mold chuck, and can move the mold 3 up and down. The system controller 8 controls the substrate stage 10 so that the imprint material 14 on the substrate 1 is located directly below a mesa portion 12 having a pattern portion 13 in the mold 3 (see FIG. 2B). Thereafter, the system controller 8 drives the imprint head 2 downward, that is, in a direction in which the substrate 1 is arranged, and brings the imprint material 14 on the substrate into contact with the mesa portion 12.

The mesa portion 12 of the mold 3 will be described with reference to FIGS. 2A-B. The mesa portion 12 is a stepped portion where a pattern is formed on the surface of the mold 3. The mesa portion 12 is formed on a lower surface of the mold 3 facing the substrate 1, and protrudes downward by about 30 μm from a peripheral region 21 surrounding the mesa portion 12 on the lower surface. Since the mesa portion 12 protrudes downward, it is possible to suppress the imprint material 14 from moving to a portion other than the pattern portion formed in the mesa portion 12 during filling of the imprint material 14.

Returning to the description of FIG. 1. The irradiation unit 6 irradiates the mesa portion 12 with UV light in order to cure the filled imprint material 14. By irradiating the mesa portion 12 with UV light, the imprint material 14 filled in the pattern portion 13 of the mesa portion 12 is cured, and a pattern of the imprint material 14 is formed on the substrate. After pattern formation, the system controller 8 drives the imprint head 2 upward, whereby the mesa portion 12 is separated from the cured imprint material 14 (mold release). The imprint material 14 to which the pattern is transferred and which is cured remains on the substrate. The reason why the imprint material 14 remains on the substrate is that an adhesion layer is applied to the surface of the substrate 1 in advance, and an adhesive force between the adhesion layer and the imprint material 14 is larger than an adhesive force between the imprint material 14 and the mesa portion 12.

Summarizing the above steps, the imprint process includes the following steps.
(a) Application of the imprint material 14 to the substrate 1 (application step).
(b) Contact between the mesa portion 12 and the imprint material 14 on the substrate (contact step).
(c) Curing of the imprint material 14 (curing step).
(d) Separation of the mesa portion 12 and the substrate 1 (mold release step).

This series of steps is continuously performed for each shot region of the substrate 1, whereby a plurality of patterns can be transferred to the surface of the substrate 1. These operations are controlled by the system controller 8.

In the contact (contact step) between the mesa portion 12 and the imprint material 14 on the substrate 1, it is necessary to replace gas in a space between the mold 3 and the substrate 1 with a permeable gas in order to prevent occurrence of a bubble defect. Further, in the separation (mold release step) of the mesa portion 12 and the substrate 1, it is necessary to purge an anti-static gas and perform gas replacement in order to prevent separation charging that occurs when the mold 3 is released from the substrate 1. As described above, the height of the mesa portion 12 is about 30 μm. In that case, an interval of a space between a mesa peripheral portion and the imprint material 14 in a state where the mesa portion 12 and the imprint material 14 on the substrate are in close contact with each other is about 30 μm (narrow gap). Since it is necessary to purge an anti-static gas and perform gas replacement in such a narrow space, there is a problem that gas replacement takes a long time. The present embodiment addresses this problem.

In FIG. 1, gas purge piping 5 is piping for introducing a permeable process gas and a process gas having an anti-static effect, and is two systems of gas piping of an anti-static gas (first gas) and a permeable gas (second gas) which are independent from each other. Each process gas can be switched on/off by an air-operated valve, and is configured such that a flow rate can be adjusted by a mass flow controller. Control is performed by a programmable logic controller (PLC) built into the gas controller 7. The process gas introduced from the gas purge piping 5 passes through a nozzle 9 (first nozzle, second nozzle) which is a gas introduction part, and is introduced from the imprint head 2 to a side surface of the mold 3. A groove is formed in a peripheral region 21 of a surface of the mold 3 facing the substrate 1. This groove constitutes a gas flow path 11 (first flow path) from an end of the mold 3 toward the mesa portion 12 as shown in FIGS. 2A-B. The gas flow path 11 has a flow path inlet for a portion of the nozzle 9 to which the anti-static gas is supplied. The anti-static gas introduced from the flow path inlet passes through the gas flow path 11 and is introduced to the imprint material 14 on the substrate and the periphery of the pattern of the mold 3. In one example, the gas flow path 11 is an enlarged flow path having a shape that widens and becomes shallower as the groove becomes closer to the mesa portion 12. Specifically, a cross section of the gas flow path 11 has a shape with a small aspect ratio and a large depth at the inlet, which makes it easy to introduce a nozzle jet, and has a shape with a large aspect ratio and a small depth toward the back (center side of the mold). It is possible to suppress flow turbulence by changing the cross-sectional shape so that the Reynolds number of each cross section does not change significantly. Although it also depends on the kinematic viscosity of the fluid to be used, it is preferable that the depth of the shallowest part of the groove is about 0.5 to 2 mm. This is because a better result is obtained when the groove is made deeper than the boundary layer displacement thickness of the fluid.

The above description is for a portion of the gas flow path 11 to which the anti-static gas is supplied. In the present embodiment, it is not necessary to provide a flow path inlet for a portion to which the permeable gas is supplied. The reason why it is not necessary to provide a flow path inlet for the portion to which the permeable gas is supplied is that, after the imprint material 14 is applied by the dispenser, introduction of the permeable gas is performed while the substrate 1 is moved below the imprint head 2. By relative movement of the imprint head 2 and the substrate 1 in directions parallel to each other, the fluid comes to circulate due to a shear flow generated in the gas space, and therefore it is possible to perform gas replacement even in a narrow gap. On the other hand, at the time of supplying the anti-static gas, since the substrate stage 10 is not driven, gas introduction is more difficult. Therefore, the above-mentioned gas flow path 11 is required. Further, pressure loss is reduced by providing a fine concavo-convex pattern of about several tens of μm called a riblet structure on the flow path surface to reduce fluid resistance. Thereby, it becomes possible to replace gas in a space around the pattern of the imprint material 14 and the mold 3 with a small amount of gas purge.

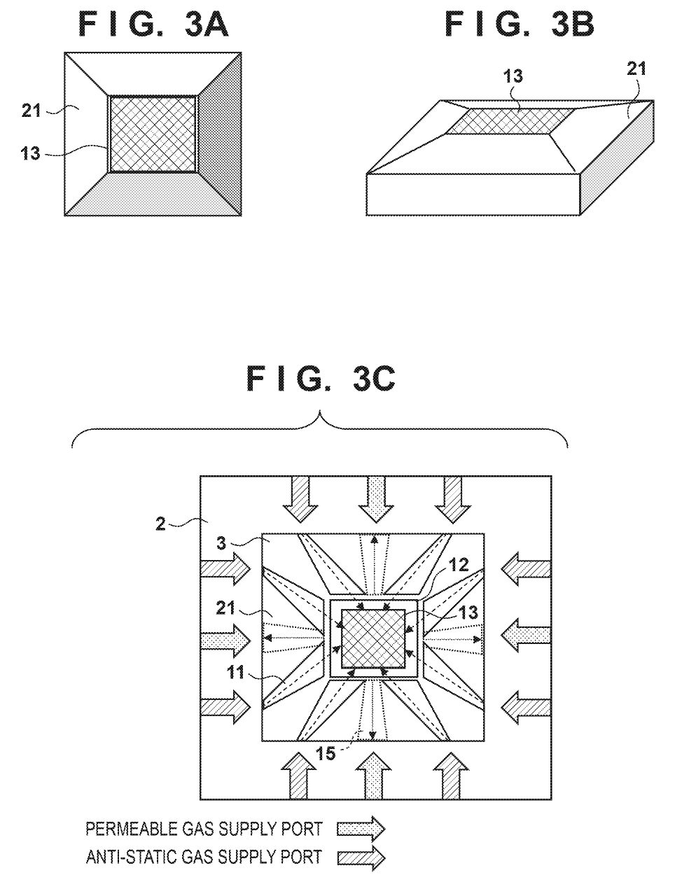

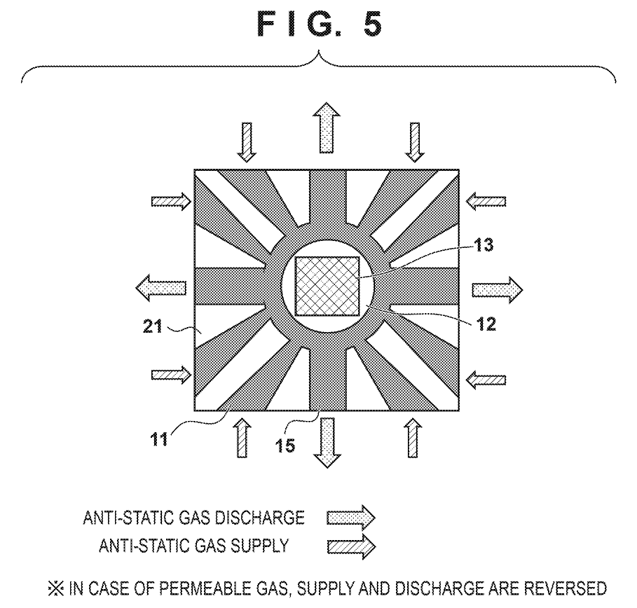

FIGS. 3A-C show modifications of the mold 3. In FIGS. 3A and 3B, the peripheral region 21 has a shape whose thickness increases as it approaches the pattern portion 13. In FIG. 3C, the mold 3 has, in addition to the above-mentioned gas flow path 11, four lines of gas flow paths 15 (second flow path) formed in the vicinity of a position where the permeable gas is supplied. When purging the anti-static gas, as shown in FIG. 5, when the anti-static gas is supplied to the space through the gas flow path 11, the gas existing in the space is pushed out through the gas flow path 15 and discharged to the outside. Thereby, gas replacement is promoted. Note that, when purging the permeable gas, the arrows in FIG. 5 are in the opposite direction. That is, when the permeable gas is supplied to the space, the gas existing in the space is pushed out through the gas flow path 11 and discharged to the outside.

According to the configuration as described above, quick gas replacement for a narrow gap space is possible without the need to provide a through-hole in the mold and without the need to provide a controller for switching control between gas supply and gas suction. In the present embodiment, in order to prevent gas from entering between the mold 3 and the substrate 1 and causing a bubble defect during imprinting, the permeable gas is purged to perform gas replacement. Next, in order to prevent separation charging that occurs when the mold 3 is released from the substrate 1, an anti-static gas is purged to perform gas replacement during mold release. In that case, in a state where the imprint material 14 and the mold 3 are in close contact with each other, it is possible to purge a gas having an anti-static effect and replace gas in the surrounding space of the imprint material 14 and the mold 3. Further, for the permeable gas and the anti-static gas, optimal gas combinations can be appropriately selected and used according to materials and processes.

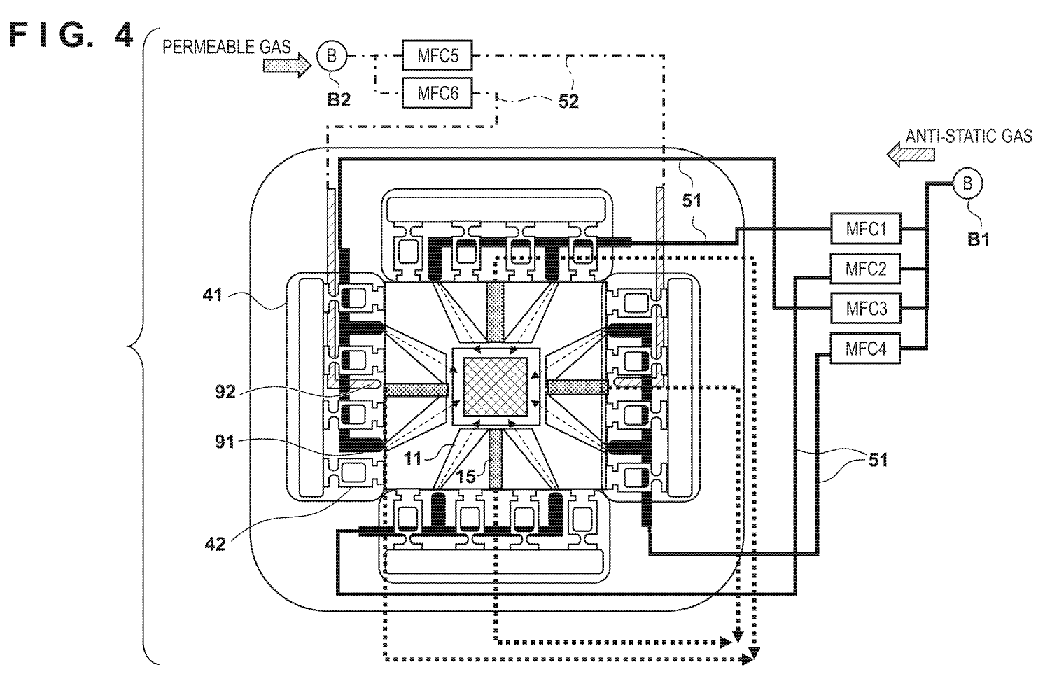

As shown in FIG. 4, the imprint head 2 can be provided with a deformation mechanism 41 that deforms the mold 3 by applying a force to a side surface of each side of the mold 3. The deformation mechanism 41 can include a plurality of actuators 42 that apply a force to the side surface of the mold 3. By independently operating each of the plurality of actuators 42, a shape of a pattern formed in the mold 3 can be corrected. The number of actuators arranged on each side can be determined by the size of the mold 3, an envisioned deformation shape, and a correction amount.

In FIG. 4, the gas purge piping 5 includes an anti-static gas piping 51 through which an anti-static gas passes and a permeable gas piping 52 through which a permeable gas passes. The imprint apparatus has a first supplier S1 that supplies an anti-static gas (first gas) for replacement with air in a space between the mold 3 and the substrate 1. The first supplier S1 can include a valve B1, mass flow controllers MFC1 to MFC4, the anti-static gas piping 51, and a nozzle 91 (first nozzle). The anti-static gas introduced into the anti-static gas piping 51 passes through the valve B1 and any one of the mass flow controllers MFC1 to MFC4, and is injected from a nozzle 91 connected to the anti-static gas piping 51.

Further, the imprint apparatus has a second supplier S2 that supplies a permeable gas (second gas) for replacement with air in a space between the mold 3 and the substrate 1. The second supplier S2 can include a valve B2, mass flow controllers MFC5 to MFC6, a permeable gas piping 52, and a nozzle 92 (second nozzle). The permeable gas introduced into the permeable gas piping 52 passes through the valve B2 and any one of the mass flow controllers MFC5 to MFC6, and is injected from a nozzle 92 connected to the permeable gas piping 52.

Here, the nozzle 91 is arranged between the plurality of actuators 42 and is arranged so that the anti-static gas is introduced toward the gas flow path 11. The nozzle 92 is arranged between the plurality of actuators 42 and is arranged so that the permeable gas is introduced into the space between the mold 3 and the substrate 1. In this way, since the nozzle 91 and the nozzle 92 can be arranged between the plurality of actuators 42, there is an advantage of not leading to an increase in size of the apparatus.

### Embodiment of Article Manufacturing Method

A pattern of a cured product formed in a forming step of forming a pattern on a substrate using the imprint apparatus is used permanently for at least a part of various articles, or used temporarily when manufacturing various articles. The articles are an electric circuit element, an optical element, a MEMS, a recording element, a sensor, a mold, or the like. Examples of the electric circuit element include volatile or non-volatile semiconductor memories such as a DRAM, an SRAM, flash memory, and an MRAM, and semiconductor elements such as an LSI, a CCD, an image sensor, and an FPGA. Examples of the mold include an imprint mold and the like.

The pattern of the cured product is used as it is as a constituent member of at least a part of the article, or is temporarily used as a resist mask. After etching, ion implantation, or the like is performed in a substrate processing step, the resist mask is removed.

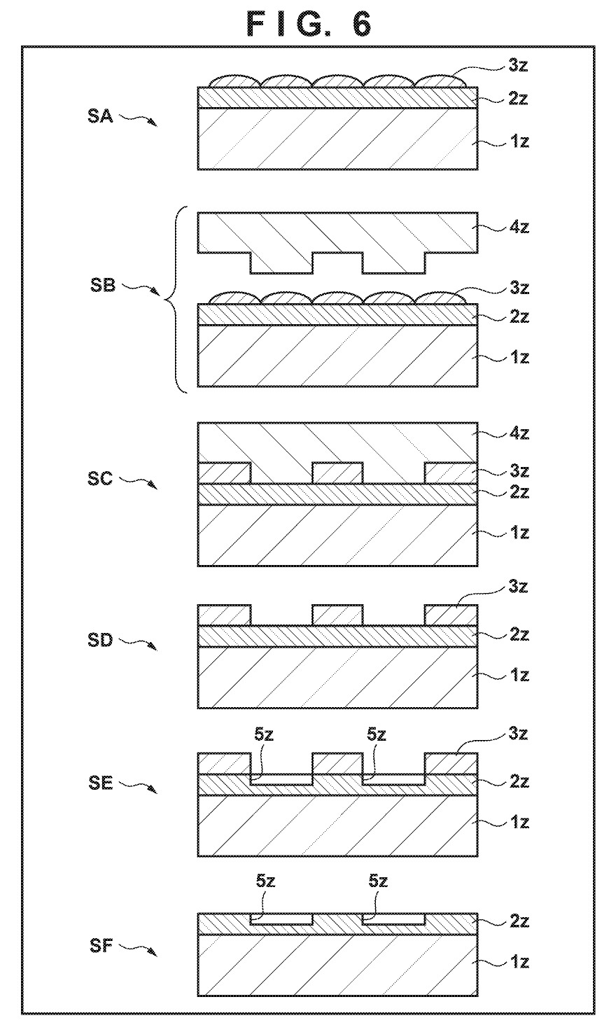

Next, an article manufacturing method will be described with reference to FIG. 6.

In step SA, a substrate 1z such as a silicon substrate on whose surface a material to be processed 2z such as an insulator is formed is prepared, and subsequently, an imprint material 3z is applied to the surface of the material to be processed 2z by an inkjet method or the like. Here, a state where a plurality of droplet-shaped imprint materials 3z are applied onto the substrate is shown.

In step SB, an imprint mold 4z is opposed with its side on which a concavo-convex pattern is formed directed toward the imprint material 3z on the substrate.

In step SC, the substrate 1z to which the imprint material 3z is applied and the mold 4z are brought into contact with each other, and pressure is applied. The imprint material 3z is filled in a gap between the mold 4z and the material to be processed 2z. In this state, when light is emitted through the mold 4z as energy for curing, the imprint material 3z is cured.

In step SD, after the imprint material 3z is cured, when the mold 4z and the substrate 1z are separated, a pattern of a cured product of the imprint material 3z is formed on the substrate 1z. This pattern of the cured product has a shape in which a concave portion of the mold corresponds to a convex portion of the cured product and a convex portion of the mold corresponds to a concave portion of the cured product, that is, the concavo-convex pattern of the mold 4z is transferred to the imprint material 3z.

In step SE, when etching is performed using the pattern of the cured product as an etching resistant mask, a portion where the cured product is absent or remains thinly on the surface of the material to be processed 2z is removed to become a groove 5z.

In step SF, when the pattern of the cured product is removed, an article in which the groove 5z is formed on the surface of the material to be processed 2z can be obtained. Although the pattern of the cured product is removed here, it may be used as a film for interlayer insulation included in a semiconductor element or the like, that is, as a constituent member of an article, without being removed even after processing.

According to the present disclosure, a technique advantageous for achieving both defect reduction and throughput is provided.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-068954, filed on Apr. 18, 2025 which is hereby incorporated by reference herein in its entirety.

What is claimed is:

1. An imprint apparatus that transfers a pattern of a mold onto a substrate, comprising:
a first supplier that supplies a first gas for replacement with air in a space between the mold and the substrate,
wherein the first supplier has a first nozzle that injects the first gas,
wherein the mold has a mesa portion in which the pattern is formed and a peripheral region surrounding the mesa portion, and the peripheral region is provided with a first flow path from an end of the mold toward the mesa portion and a second flow path from the mesa portion toward the end of the mold,
wherein the first nozzle is arranged toward the first flow path so that the first gas is introduced into the first flow path, and when the first gas is supplied through the first flow path by the first supplier, a gas in the space is discharged to the outside through the second flow path.

2. The imprint apparatus according to claim 1, wherein the first gas is an anti-static gas.

3. The imprint apparatus according to claim 1, wherein the first flow path is a groove formed in the peripheral region.

4. The imprint apparatus according to claim 3, wherein the first flow path has a shape that widens and becomes shallower as the groove becomes closer to the mesa portion.

5. The imprint apparatus according to claim 1, wherein the second flow path is a groove formed in the peripheral region.

6. The imprint apparatus according to claim 1, further comprising a second supplier that supplies a second gas for replacement with air in the space, wherein the second supplier has a second nozzle that injects the second gas toward the space.

7. The imprint apparatus according to claim 6, wherein the second gas is a permeable gas that permeates through the mold.

8. The imprint apparatus according to claim 6, wherein, when the second gas is supplied by the second supplier, a gas in the space is discharged to the outside through the first flow path.

9. The imprint apparatus according to claim 6, further comprising a deformation mechanism that deforms the mold, wherein the deformation mechanism includes a plurality of actuators that apply a force to a side surface of the mold, and the first nozzle and the second nozzle are each arranged between the plurality of actuators.

10. An article manufacturing method, comprising:
forming a pattern on a substrate using the imprint apparatus according to claim 1; and
processing the substrate on which the pattern is formed,
wherein an article is manufactured from the substrate on which the processing is performed.
